(19) United States
(12) Patent Application Publication
(10) Pub. No.: US 2021/0225884 A1
(43) Pub. Date: Jul. 22, 2021

(54) ARRAY SUBSTRATE, MANUFACTURING METHOD THEREOF, AND DISPLAY PANEL

(71) Applicant: Shenzhen China Star Optoelectronics Semiconductor Display Technology Co., LTD., Shenzhen, Guangdong (CN)

(72) Inventors: Hui XIA, Shenzhen, Guangdong (CN); Zhiwei TAN, Shenzhen, Guangdong (CN)

(21) Appl. No.: 16/304,325

(22) PCT Filed: Aug. 30, 2018
(86) PCT No.: PCT/CN2018/103269

§ 371 Date: Nov. 26, 2018

(30) Foreign Application Priority Data
Jun. 27, 2018 (CN) 201810677642.3

(51) Int. Cl. H01L 27/12

(52) U.S. Cl. CPC H01L 27/1222; H01L 27/127

(57) ABSTRACT

An array substrate, a manufacturing method thereof, and a display panel are provided in the present application. A gate electrode and source and drain electrodes of different thickness are formed on an electroplated substrate by metal electroplating. By using a height difference between the gate electrode and the source and drain electrodes, a dielectric layer covering the gate electrode and exposing the source and drain electrodes is formed on a substrate, so that an active layer is electrically connected to the source and drain electrodes. Moreover, separation is realized by means of the dielectric layer and the gate electrode, so an etching stop layer is not needed, which simplifies an IGZO manufacturing process and reduces production costs.

### 1. FIELD OF THE DISCLOSURE

The present invention relates to the field of a panel manufacturing technology, and in particular, to an array substrate, a manufacturing method thereof, and a display panel.

### 2. DESCRIPTION OF THE RELATED ART

Currently, driving technologies for commonly-used thin film transistors (TFT) include amorphous silicon TFT (a-Si TFT), low temperature poly-silicon TFT (LTPS TFT), and indium gallium zinc oxide TFT (IGZO TFT). Simply put, IGZO is a new semiconductor material which has increased electron mobility and a higher on-state current, when compared to the a-Si TFT. Therefore, IGZO is extensively used in TFT devices in the display industry.

A manufacturing process for back channel etched (BCE) bottom-gate IGZO TFT is more complicated, and the manufacturing process needs an etching stop layer (ESL) to prevent the IGZO at a channel from being damaged during a process of wet etching a metal electrode layer to form source and drain electrodes.

### SUMMARY

The present invention provides an array substrate, a manufacturing method thereof, and a display panel to simplify conventional IGZO manufacturing processes and reduce production costs.

To achieve the above objectives, the present invention provides the following technical solutions:

The present invention provides a manufacturing method of an array substrate, including following steps:

Step S10: providing a substrate, a metal layer being formed on the substrate, and an electroplated layer being formed on the substrate via a patterning process.

Step S20: forming a gate electrode and source and drain electrodes which have different thicknesses on the electroplated layer.

Step S30: forming a dielectric layer on the gate electrode, wherein the dielectric layer covers the gate electrode and the substrate.

Step S40: forming an active layer on the dielectric layer.

Step S50: forming a passivation layer on the active layer.

In the manufacturing method of the present invention, the electroplated layer includes a first base layer, a second base layer, and a third base layer, and the second base layer is disposed between the first base layer and the third base layer.

In the manufacturing method of the present invention, the gate electrode is formed on the second base layer, and the source and drain electrodes are formed on the first base layer and the third base layer.

In the manufacturing method of the present invention, the above-mentioned Step S40 includes:

Step S401: forming the active layer on the dielectric layer, wherein the dielectric layer covers the active layer and the source and drain electrodes.

Step S402: coating a first photoresist layer on the active layer.

Step S403: performing exposure and development processes on the first photoresist layer.

Step S404: etching the active layer, during which the active layer between and on the source and drain electrodes is preserved.

Step S405: removing the first photoresist layer.

In the manufacturing method of the present invention, the gate electrode and the source and drain electrodes are formed in the same manufacturing process.

In the manufacturing method of the present invention, the gate electrode and the source and drain electrodes are formed by metal electroplating.

In the manufacturing method of the present invention, an electric potential for formation of the source and drain electrodes is higher than an electric potential for formation of the gate electrode.

In the manufacturing method of the present invention, the thickness of the source and drain electrodes is greater than the thickness of the gate electrode.

The present invention further provides an array substrate, wherein the array substrate is manufactured by using steps including:

Step S10: providing a substrate, a metal layer being formed on the substrate, an electroplated layer being formed on the substrate via a patterning process.

Step S20: forming a gate electrode and source and drain electrodes which have different thicknesses on the electroplated layer, wherein the thickness of the source and drain electrodes is greater than the thickness of the gate electrode.

Step S30: forming a dielectric layer on the gate electrode, wherein the dielectric layer covers the gate electrode and the substrate.

Step S40: forming an active layer on the dielectric layer.

Step S50: forming a passivation layer on the active layer.

In the array substrate of the present invention, the electroplated layer includes a first base layer, a second base layer, and a third base layer, and the second base layer is disposed between the first base layer and the third base layer.

In the array substrate of the present invention, the gate electrode is formed on the second base layer, and the source and drain electrodes are formed on the first base layer and the third base layer.

In the array substrate of the present invention, the above-mentioned Step S40 includes:

Step S401: forming the active layer on the dielectric layer, wherein the dielectric layer covers the active layer and the source and drain electrodes.

Step S402: coating a first photoresist layer on the active layer.

Step S403: performing exposure and development processes on the first photoresist layer.

Step S404: etching the active layer, during which the active layer between and on the source and drain electrodes is preserved.

Step S405: removing the first photoresist layer.

In the array substrate of the present invention, the gate electrode and the source and drain electrodes are formed in the same manufacturing process.

In the array substrate of the present invention, the gate electrode and the source and drain electrodes are formed in the same manufacturing process, and an electric potential for formation of the source and drain electrodes is higher than an electric potential for formation of the gate electrode.

The present invention further provides a display panel which includes an array substrate, wherein the array substrate is made by using steps including:

Step S10: providing a substrate, a metal layer being formed on the substrate, an electroplated layer being formed on the substrate via a patterning process.

Step S20: forming a gate electrode and source and drain electrodes which have different thicknesses on the electroplated layer.

Step S30: forming a dielectric layer on the gate electrode, wherein the dielectric layer covers the gate electrode and the substrate.

Step S40: forming an active layer on the dielectric layer.

Step S50: forming a passivation layer on the active layer.

In the display panel of the present invention, the electroplated layer includes a first base layer, a second base layer and a third base layer, and the second base layer is disposed between the first base layer and the third base layer.

In the display panel of the present invention, the gate electrode is formed on the second base layer, and the source and drain electrodes are formed on the first base layer and the third base layer.

In the display panel of the present invention, the above-mentioned Step S40 includes:

Step S401: forming the active layer on the dielectric layer, wherein the dielectric layer covers the active layer and the source and drain electrodes.

Step S402: coating a first photoresist layer on the active layer.

Step S403: performing exposure and development processes on the first photoresist layer.

Step S404: etching the active layer, during which the active layer between and on the source and drain electrodes is preserved.

Step S405: removing the first photoresist layer.

In the display panel of the present invention, the gate electrode and the source and drain electrodes are formed in the same manufacturing process.

In the display panel of the present invention, the gate electrode and the source and drain electrodes are formed in the same manufacturing process, and an electric potential for formation of the source and drain electrodes is higher than an electric potential for formation of the gate electrode.

Advantageous effects of the present invention: The gate electrode and the source and drain electrodes of different thickness are formed on the electroplated substrate by metal electroplating. By using a height difference between the gate electrode and the source and drain electrodes, the dielectric layer covering the gate electrode and exposing the source and drain electrodes is formed on the substrate, so that the active layer is electrically connected to the source and drain electrodes. Moreover, separation is realized by means of the dielectric layer and the gate electrode, so an etching stop layer is not needed, which simplifies an IGZO manufacturing process and reduces production costs.

### BRIEF DESCRIPTION OF THE DRAWINGS

In order to more clearly illustrate the embodiments of the present disclosure or related art, figures which will be described in the embodiments are briefly introduced hereinafter. It is obvious that the drawings are merely for the purposes of illustrating some embodiments of the present disclosure, a person having ordinary skill in this field can obtain other figures according to these figures without an inventive work or paying the premise.

FIG. 1 is a process flow diagram illustrating a manufacturing method of an array substrate; and

FIGS. 2A to 2H are cross-sectional views illustrating different steps of the method for manufacturing the array substrate.

### DETAILED DESCRIPTION OF THE EMBODIMENTS

Embodiments of the present disclosure are described in detail with reference to the accompanying drawings as follows. Directional terms such as up/down, right/left and the like may be used for the purpose of enhancing a reader's understanding about the accompanying drawings, but are not intended to be limiting. Specifically, the terminologies in the embodiments of the present disclosure are merely for the purpose of describing certain embodiments, but not intended to limit the scope of the invention. The same reference numbers are used throughout the drawings to refer to the same or similar parts.

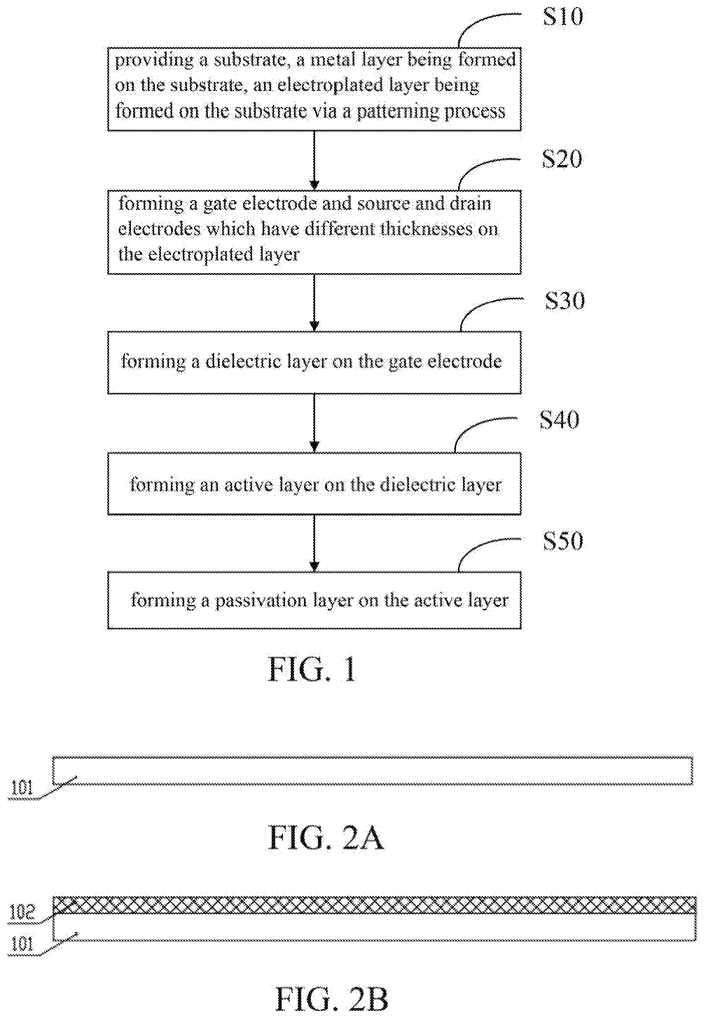

Please refer to FIG. 1 which shows a process flow diagram illustrating a manufacturing method of an array substrate according to one embodiment of the present invention. The manufacturing method includes:

Step S10: providing a substrate, a metal layer being formed on the substrate, an electroplated layer being formed on the substrate via a patterning process.

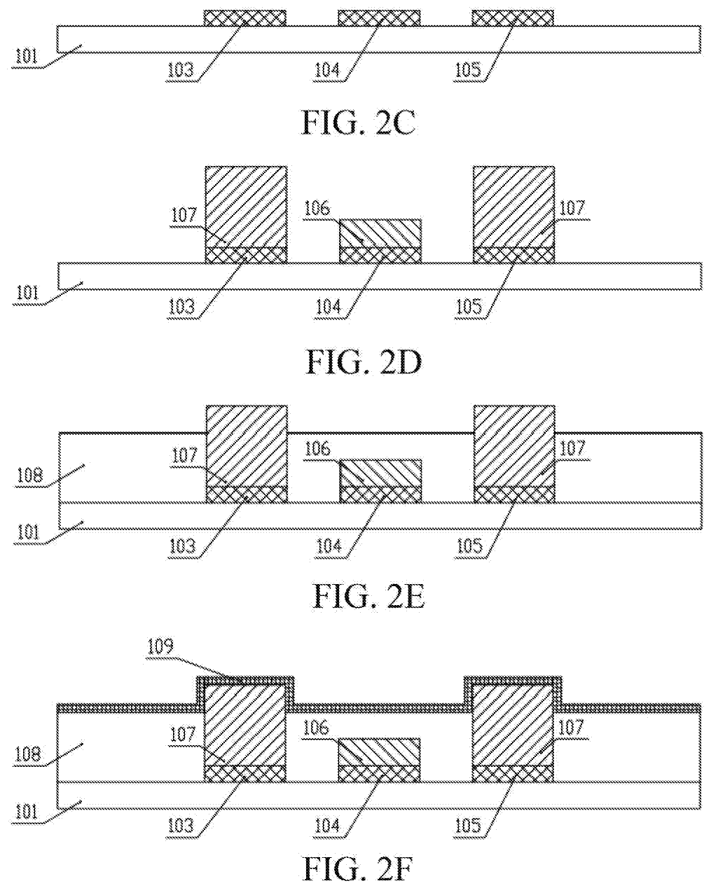

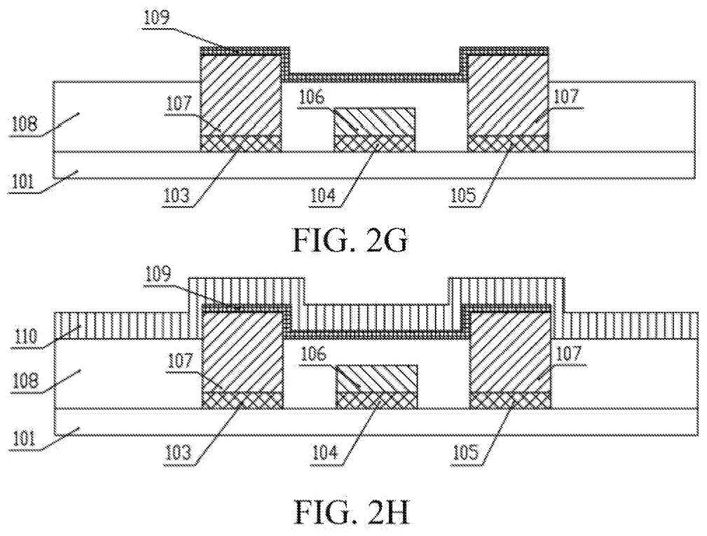

As shown in FIG. 2A, a substrate 101 is provided. The substrate 101 is made of one of a glass substrate, a quartz substrate, a resin substrate, and other suitable material.

As shown in FIG. 2B, a first metal layer 102 is formed on the substrate 101. The first metal layer is an electroplating primitive layer. It is preferable that the thickness of the metal layer is about 200 Å. The first metal layer 102 preferably consists of molybdenum.

As shown in FIG. 2C, a first photoresist layer is coated on the first metal layer 102. A mask plate (not illustrated) is used for performing an exposure process. After development and etching processes, the first metal layer 102 is patterned, and the first photoresist layer is removed, so that the first metal layer 102 forms an electroplated layer.

The electroplated layer includes a first base layer 103, a second base layer 104 and a third base layer 105, and the second base layer 104 is disposed between the first base layer 103 and the third base layer 105.

Step S20: forming a gate electrode and source and drain electrodes which have different thicknesses on the electroplated layer.

As shown in FIG. 2D, this step mainly utilizes metal electroplating; however, the present invention is not limited to the metal electroplating technique. The gate electrode 106 and the source and drain electrodes 107 are formed on the electroplated layer at the same time. In other words, the gate electrode 106 and the source and drain electrodes 107 are formed in the same manufacturing process.

In this embodiment, the gate electrode 106 and the source and drain electrodes 107 are made of the same or different metal materials; the metal material can be molybdenum, aluminum, aluminum-nickel alloy, molybdenum-tungsten alloy, chromium, copper, or other suitable metal. The metal material can also be a combination of the above-mentioned materials. It is preferable that the gate electrode 106 and the source and drain electrodes 107 consist of copper.

To perform metal electroplating, the structure of FIG. 2C is placed in an electrolytic cell for electroplating corresponding metals. The first base layer 103 or the third base layer 105 is connected to an electric potential different from an electric potential of the second base layer 104. The first base layer 103 and the third base layer 105 are at the same electric potential. In this step, an electric potential difference exists between different base layers, so different base layers have different metal deposition speeds, as shown in FIG. 2D.

In the present embodiment, the electric potential for formation of the source and drain electrodes 107 is higher than the electric potential for formation of the gate electrode 106. As a result, during the same time period, the source and drain electrodes 107 on the first base layer 103 and the third base layer 105 have a thickness greater than a thickness of the gate electrode 105 on the second base layer 104. It is preferable that, the thickness of the gate electrode 106 is 5000 Å, and the thickness of the source and drain electrodes 107 is 1 μm.

Moreover, the gate electrode 106 is disposed on the second base layer 104, and the source and drain electrodes 107 are disposed on the first base layer 103 and the third base layer 105.

Step S30: forming a dielectric layer on the gate electrode, wherein the dielectric layer covers the gate electrode and the substrate and exposes a portion of the source and drain electrodes.

As shown in FIG. 2E, the step of forming a dielectric layer 108 on the gate electrode 106 is realized by using a chemical method where an organic insulating material with a good leveling property is used to be deposited on the substrate 101. The dielectric layer 108 covers the gate electrode 106 and the substrate 101 and exposes a portion of the source and drain electrodes 107.

S40: forming an active layer on the dielectric layer.

As shown in FIG. 2F, in this step an active layer 109 is first formed on the dielectric layer 108 and the source and drain electrodes 107. The active layer 109 preferably consists of a metal oxide. Then, a first photoresist layer is formed on the active layer 109. A mask plate (not illustrated) is used for performing an exposure process. After performing a development process on the first photoresist layer, the first photoresist layer between and on the source and drain electrodes 107 are preserved. After that, the active layer 109 is etched, and during etching of the active layer 109, the active layer 109 between and on the source and drain electrodes 107 is preserved. As shown in FIG. 2G, the active layer 109 covers the source and drain electrodes 107 and the dielectric layer 108 between the source and drain electrodes 107.

Step S50: forming a passivation layer on the active layer.

As shown in FIG. 2H, a passivation layer 110 is formed on the active layer 109 and the dielectric layer 108. The passivation layer 110 covers the active layer 109 and the dielectric layer 108. The passivation layer 110 preferably consists of silicon nitride.

The present invention further provides an array substrate. The array substrate is manufactured by using the manufacturing method of the array substrate mentioned above.

The present invention also provides a display panel. The display panel includes the array substrate mentioned above.

In summary, the present invention provides the array substrate, the manufacturing method thereof, and the display panel. The gate electrode and the source and drain electrodes of different thickness are formed on the electroplated substrate through metal electroplating. By using a height difference between the gate electrode and the source and drain electrodes, the dielectric layer covering the gate electrode and exposing the source and drain electrodes is formed on the substrate, so that the active layer is electrically connected to the source and drain electrodes. Moreover, separation is realized by means of the dielectric layer and the gate electrode, so an etching stop layer is not needed, which simplifies an IGZO manufacturing process and reduces production costs.

It is to be understood that the above descriptions are merely the preferable embodiments of the present invention and are not intended to limit the scope of the present invention. Equivalent changes and modifications made in the spirit of the present invention are regarded as falling within the scope of the present invention.

What is claimed is:

1. A manufacturing method for an array substrate, comprising steps of:
providing a substrate, a metal layer being formed on the substrate, an electroplated layer being formed on the substrate via a patterning process;
forming a gate electrode and source and drain electrodes which have different thicknesses on the electroplated layer;
forming a dielectric layer on the gate electrode, wherein the dielectric layer covers the gate electrode and the substrate;
forming an active layer on the dielectric layer; and
forming a passivation layer on the active layer.

2. The manufacturing method according to claim 1, wherein the electroplated layer includes a first base layer, a second base layer, and a third base layer, and the second base layer is disposed between the first base layer and the third base layer.

3. The manufacturing method according to claim 2, wherein the gate electrode is formed on the second base layer, and the source and drain electrodes are formed on the first base layer and the third base layer.

4. The manufacturing method according to claim 1, wherein forming the active layer on the dielectric layer comprises:
forming the active layer on the dielectric layer, wherein the dielectric layer covers the active layer and the source and drain electrodes;
coating a first photoresist layer on the active layer;
performing exposure and development processes on the first photoresist layer;
etching the active layer, during which the active layer between and on the source and drain electrodes is preserved; and
removing the first photoresist layer.

5. The manufacturing method according to claim 1, wherein the gate electrode and the source and drain electrodes are formed in the same manufacturing process.

6. The manufacturing method according to claim 5, wherein the gate electrode and the source and drain electrodes are formed by metal electroplating.

7. The manufacturing method according to claim 6, wherein an electric potential for formation of the source and drain electrodes is higher than an electric potential for formation of the gate electrode.

8. The manufacturing method according to claim 1, wherein the thickness of the source and drain electrodes is greater than the thickness of the gate electrode.

9. An array substrate, wherein the array substrate is manufactured by using steps comprising:
providing a substrate, a metal layer being formed on the substrate, an electroplated layer being formed on the substrate via a patterning process;
forming a gate electrode and source and drain electrodes which have different thicknesses on the electroplated layer, wherein the thickness of the source and drain electrodes is greater than the thickness of the gate electrode;
forming a dielectric layer on the gate electrode, wherein the dielectric layer covers the gate electrode and the substrate;
forming an active layer on the dielectric layer; and
forming a passivation layer on the active layer.

10. The array substrate according to claim 9, wherein the electroplated layer includes a first base layer, a second base layer and a third base layer, and the second base layer is disposed between the first base layer and the third base layer.

11. The array substrate according to claim 10, wherein the gate electrode is formed on the second base layer, and the source and drain electrodes are formed on the first base layer and the third base layer.

12. The array substrate according to claim 9, wherein forming the active layer on the dielectric layer comprises:
forming the active layer on the dielectric layer, wherein the dielectric layer covers the active layer and the source and drain electrodes;
coating a first photoresist layer on the active layer;
performing exposure and development processes on the first photoresist layer;
etching the active layer, during which the active layer between and on the source and drain electrodes is preserved; and
removing the first photoresist layer.

13. The array substrate according to claim 9, wherein the gate electrode and the source and drain electrodes are formed in the same manufacturing process.

14. The array substrate according to claim 9, wherein the gate electrode and the source and drain electrodes are formed in the same manufacturing process, and an electric potential for formation of the source and drain electrodes is higher than an electric potential for formation of the gate electrode.

15. A display panel comprising an array substrate, wherein the array substrate is manufactured by using steps comprising:
providing a substrate, a metal layer being formed on the substrate, an electroplated layer being formed on the substrate via a patterning process;
forming a gate electrode and source and drain electrodes which have different thicknesses on the electroplated layer;
forming a dielectric layer on the gate electrode, wherein the dielectric layer covers the gate electrode and the substrate;
forming an active layer on the dielectric layer; and
forming a passivation layer on the active layer.

16. The display panel according to claim 15, wherein the electroplated layer includes a first base layer, a second base layer and a third base layer, and the second base layer is disposed between the first base layer and the third base layer.

17. The display panel according to claim 16, wherein the gate electrode is formed on the second base layer, and the source and drain electrodes are formed on the first base layer and the third base layer.

18. The display panel according to claim 15, wherein forming the active layer on the dielectric layer comprises:
forming the active layer on the dielectric layer, wherein the dielectric layer covers the active layer and the source and drain electrodes;
coating a first photoresist layer on the active layer;
performing exposure and development processes on the first photoresist layer;
etching the active layer during which the active layer between and on the source and drain electrodes is preserved; and
removing the first photoresist layer.

19. The display panel according to claim 15, wherein the gate electrode and the source and drain electrodes are formed ill the same manufacturing process.

20. The display panel according to claim 15, wherein the gate electrode and the source and drain electrodes are formed in the same manufacturing process, and an electric potential for formation of the source and drain electrodes is higher than an electric potential for formation of the gate electrode.
